(19) United States
(12) Patent Application Publication
(10) Pub. No.: US 2008/0131611 A1
(43) Pub. Date: Jun. 5, 2008

(54) Method for Application of a Thermal Barrier Coating and Resultant Structure Thereof

(76) Inventors: Derek D. Hass, Charlottesville, VA (US); Haydn N.G. Wadley, Keswick, VA (US)

Correspondence Address: NOVAK DRUCE DELUCA + QUIGG LLP, 1300 EYE STREET NW, SUITE 1000 WEST TOWER, WASHINGTON, DC, 20005, US

(21) Appl. No.: 10/566,316

(22) PCT Filed: Jul. 28, 2004
(86) PCT No.: PCT/US2004/024232

§ 371 Date: Feb. 14, 2006

Related U.S. Application Data
(60) Provisional application No. 60/490,969, filed on Jul. 29, 2003.

(51) Int. Cl. C23C 4/04; C23C 16/22; C23C 16/06

(52) U.S. Cl. 427/450; 427/255.395; 427/452; 118/726

(57) ABSTRACT

Provided herein are methods and apparatuses, and resulting structures, for depositing ceramic coatings with preferred coating density, morphology and adherence for applications such as thermal protection of internally cooled components. Such components are found in, but not limited thereto, the hot sections of gas turbine and diesel engines and in turbo machinery. These coatings require a low thermal conductivity in the through thickness of the coating, high in-plane elastic compliance, high erosion and foreign object damage resistance and resistance to hot corrosion. The methods and apparatuses discussed herein provide, among other things, how to manipulate the process conditions in EB-DVD systems to deposit high quality, highly efficient TBS top coats as well as how to deposit high quality TBC top coats onto positions that are in the line-of-sight, as well as non-line of sight, of the vapor source.

### CROSS-REFERENCE TO RELATED APPLICATIONS

The present invention claims priority under 35 U.S.C. Section 119(e) of the earlier filing date of U.S. Provisional Application Ser. No. 60/490,969, filed Jul. 29, 2003, entitled “Method for Application of a Thermal Barrier Coating and Resultant Structure thereof,” the entire disclosure of which is hereby incorporated by reference herein.

The present application is also related to U.S. application Ser. No. 10/476,309, filed Oct. 29, 2003, entitled “Method and Apparatus for Efficient Application of Substrate Coating,” of which is assigned to the present assignee and is hereby incorporated by reference herein in its entirety.

### GOVERNMENT SUPPORT

This invention was made with government support under Grant Nos. N001014-98-1-0355; N00014-00-1-0147; and N00014-97-97-0106. The government has certain rights in the invention.

### BACKGROUND OF THE INVENTION

Thermal Barrier Coatings are used extensively in aircraft and industrial gas turbine engines. They typically consist of a metallic (or intermetallic) bond coat and a ceramic top coat. The bond coat is used to provide oxidation and hot corrosion protection for the substrate, usually a nickel or cobalt based superalloy, and to produce a thermally grown oxide (TGO) which provides adhesion for the top coat. The top coat is a yttria stabilized zirconia material (typically 7-8 wt. % yttria with the balance zirconia) that provides thermal insulation to the underlying metal. By insulating the metallic component, its temperature is reduced allowing it to last longer or to survive with less cooling air (cooling air reduces the performance of the engine).

There exists a need in the art for, among other things, a cost-effective method to apply high quality TBC top coatings to surfaces. Embodiments of the present invention addresses this need and provides, among other things, how to manipulate the process conditions in a EB-DVD systems to deposit high quality, highly efficient TBC top coats as well as how to deposit high quality TBC top coats onto positions that are in the line-of-sight (as well as non-line of sight) of the vapor source.

These and other objects, along with advantages and features of the invention enclosed herein, will be made more apparent from the description, drawings, and claims that follow.

### SUMMARY OF INVENTION OF THE INVENTION

Embodiments of the present invention provides a process and apparatus, and resulting structure, for depositing ceramic coatings with preferred coating density, morphology and adherence for applications such as thermal protection of internally cooled components. Such components are found, but not limited thereto, in the hot sections of gas turbine and diesel engines and in turbo machinery. These coatings require a low thermal conductivity in the through thickness of the coating, high in-plane elastic compliance, high erosion and foreign object damage resistance and resistance to hot corrosion. These performance characteristics are determined by the coatings composition, the coatings morphology and the manner in which the coating is applied. Today's coatings are applied by either an air plasma spray or electron beam evaporation process that operates under high vacuum. This latter process results in a process recipe that creates a preferred morphology of the coating. Embodiments of the present invention utilizes, among other things, a high pressure, directed vapor deposition process in which evaporation is achieved by electron beam heating, laser ablation/evaporation, resistance heating or other mechanisms of evaporation. Because embodiments of the present invention process are different to the conventional EB-physical vapor deposition process used currently, it results in a different process for creating a preferred coating(s).

An aspect of an embodiment of the present invention provides a method for forming a thermal barrier coating system in communication with at least a portion of at least one substrate. The method comprising: a) presenting at least one of the substrates to a chamber, wherein the chamber has a down stream pressure, P_{c}, with an operating range from about 0.0001 Pa to about 150 Pa; b) depositing a bond coat on at least a portion of at least one the substrates; c) presenting at least one evaporant source to the chamber; d) presenting at least one carrier gas stream to the chamber, wherein at least one of the carrier gas streams is generated from at least one nozzle; and/or e) impinging at least one the evaporant sources with at least one energetic beam in the chamber to generate an evaporated vapor flux in a main direction respective for any of the evaporant sources impinged by the energetic beam, wherein at least one evaporant source may be disposed in the nozzle. At least one of the carrier gas streams may have a pressure ratio in the operating range from about 1.01 to about 10,000,000. The substrate may have a temperature approximately equal to or greater than a melting point of the substrate. At least one of the evaporant sources generates the evaporated vapor flux and an evaporation rate in the range of about 0.00001 g/min to about 100,000 g/min. Additionally, this method may include deflecting at least one of the generated evaporated vapor fluxes by at least one of the carrier gas streams, wherein the carrier gas stream is essentially parallel to the main direction and substantially surrounds the evaporated flux, wherein the evaporated vapor flux at least partially coats at least one the substrates.

An aspect of an embodiment of the present invention provides a method for forming a thermal barrier coating system. The method comprising: a) presenting a substrate to a chamber, wherein the chamber has a down stream pressure, P_{c}, with an operating range from about 5 Pa to about 50 Pa; b) depositing a bond coat on at least a portion of at least one of the substrates; c) presenting at least one evaporant source to the chamber; d) presenting at least one carrier gas stream to the chamber, wherein at least one of the carrier gas streams is generated from at least one nozzle; and/or e) impinging at least one the evaporant sources with at least one energetic beam in the chamber to generate an evaporated vapor flux in a main direction respective for any of the evaporant sources impinged by the energetic beam, and wherein the at least one the evaporant sources may be disposed in the nozzle. At least one of the carrier gas streams may have a pressure ratio in the operating range from about 1 to about 100. The substrate may have a temperature in the range of about 15° C. and about 1,250° C. At least one of the evaporant sources generates the evaporated vapor flux and an evaporation rate in the range of about 0.1 g/min to about 100 g/min. This method may further include deflecting at least one of the generated evaporated vapor fluxes by at least one of the carrier gas streams, wherein the carrier gas stream(s) is essentially parallel to the main direction and substantially surrounds the evaporated flux, wherein the evaporated vapor flux at least partially coats at least one the substrates. The chamber may further include a substrate bias system capable of applying a DC or alternating potential to at least one of the substrates. This method may further include: a) impinging the at least one of the generated vapor flux and at least one of the carrier gas streams with a working gas generated by at least one hollow cathode arc plasma activation source to ionize the at least one of the generated vapor flux and at least one of the carrier gas streams; and/or b) attracting the ionized generated vapor flux and the carrier gas stream to a substrate surface by allowing a self-bias of the ionized gas and vapor stream or the potential to pull the ionized stream to the substrate.

An aspect of an embodiment of the present invention provides an apparatus for applying a thermal barrier coating system(s) in communication with at least a portion of at least one substrate. The apparatus comprising: a) a chamber, wherein the chamber has a down stream pressure, P_{c}, with an operating range from about 0.0001 Pa to about 150 Pa; b) at least one evaporant source is disposed in the chamber, wherein at least one of the evaporant sources generates the evaporated vapor flux and an evaporation rate in the range of about 0.00001 g/min to about 100,000 g/min; c) at least one carrier gas stream is provided in the chamber, wherein at least one of the carrier gas streams is generated from at least one nozzle, wherein at least one of the carrier gas stream has a pressure ratio in the operating range from about 1.01 to about 10,000,000; and/or d) at least one energetic beam. At least one of the energetic beams: a) impinging at least one the of the evaporant sources with at least one energetic beam in the chamber to generate an evaporated vapor flux in a main direction respective for any of the evaporant sources impinged by the energetic beam, b) deflecting at least one of the generated evaporated vapor flux by at least one of the carrier gas stream, wherein the carrier gas stream is essentially parallel to the main direction and substantially surrounds the evaporated flux, and wherein the evaporated vapor flux at least partially coats at least one of the substrates, and/or c) at least one of the substrates having a temperature approximately equal to or greater than a melting point of the substrate(s).

An aspect of an embodiment of the present invention provides an apparatus for applying a thermal barrier coating system in communication with at least a portion of at least one substrate. The apparatus comprising: a) a chamber, wherein the chamber has a down stream pressure, P_{c}, with an operating range from about 5 Pa to about 50 Pa; b) at least one evaporant source disposed in the chamber, wherein at least one of the evaporant sources generates the evaporated vapor flux and an evaporation rate in the range of about 0.1 g/min to about 100 g/min; c) at least one carrier gas stream provided in the chamber, wherein at least one of the carrier gas streams is generated from at least one nozzle, wherein at least one carrier gas stream may have a pressure ratio in the operating range from about 1 to about 100; and/or d) at least one energetic beam. The energetic beam: a) impinging at least one of the evaporant sources with at least one energetic beam in the chamber to generate an evaporated vapor flux in a main direction respective for any of the evaporant sources impinged by the energetic beam, b) deflecting at least one of the generated evaporated vapor fluxes by at least one of the carrier gas streams, wherein the carrier gas stream is essentially parallel to the main direction and substantially surrounds the evaporated flux, wherein the evaporated vapor flux at least partially coats at least one the substrate, and c) the substrate having a temperature approximately equal to or greater than a melting point of the substrate. The apparatus may further comprise: a) a substrate bias system capable of applying a DC or alternating potential to at least one of the substrates; and/or b) at least one hollow cathode arc source generating a low voltage beam, the at least one hollow cathode arc source. This apparatus may be further adapted for a) impinging the at least one of the generated vapor flux and at least one of the carrier gas stream with a working gas generated by at least one the hollow cathode arc plasma activation sources to ionize at least one of the generated vapor flux and at least one of the carrier gas stream; and b) attracting the ionized generated vapor flux and the carrier gas stream to a substrate surface by allowing a self-bias of the ionized gas and vapor stream or the potential to pull the ionized stream to the substrate.

### BRIEF DESCRIPTION OF THE FIGURES

The foregoing and other objects, features, and advantages of the present invention, as well as the invention itself, will be more fully understood from the following description of preferred embodiments, when read together with the accompanying drawings, in which:

FIG. 1 is a Micrographic depiction showing a YSZ top coat applied using EB-PVD process.

FIGS. 2(A)-(D) are graphical depictions plotting the preferred process conditions for depositing thermal barrier coatings.

FIG. 3 is a graphical depiction plotting the angle of incidence distribution for the cases of DVD and EB-PVD.

FIG. 4(A) is a photographic depiction of a DVD system that has the ability to combine focused evaporation with plasma activation for rapid, efficient deposition of various crystal structures.

FIG. 4(B) is a graphical depiction of X-ray scans that reveal the effect of plasma activation upon atomic structure.

FIG. 5 is a graphical depiction from experimental and direct simulation Monte Carlo data showing the effect of chamber pressure and pressure ratio on the deposition efficiency of copper deposited onto a 5.08 cm diameter disc located 10 cm from the evaporation source.

FIG. 6 is a graphical depiction of deposition efficiency of Aluminum deposited onto a 380 micron diameter fiber located 15 cm from the vapor source. A chamber pressure of 16 Pa is used in the EB-DVD cases. The use of a gas jet results in a more focused flux that enables a 10× increase in efficiency over EB-PVD. However, the deposition efficiency is relatively unaffected by increasing the pressure ratio because although increasing the pressure ration decreases the area of the evaporated flux (i.e. more focused flux) it also decreases the amount of Non-line of sight (NLOS) coating that occurs.

FIG. 7 is a schematic illustration of the energetic beam (e.g., e-beam) orientation in one configuration of a DVD processing system.

FIG. 8 is a graphical depiction of an XRD pattern showing the formation of an alpha alumina layer on a nickel aluminide bond coat using a vacuum heat treatment

FIGS. 9(A)-9(B) are schematic illustrations of a cross-section partial view of the substrate showing a thermal barrier coating system on the substrate in accordance with exemplary embodiments of this invention.

FIG. 10 is a schematic illustration of the directed vapor deposition (DVD) apparatus.

FIG. 11 is a schematic illustration of directed vapor deposition (DVD) apparatus including a hollow cathode arc plasma activation and substrate bias.

### DETAILED DESCRIPTION OF THE INVENTION

Vapor phase processes are widely used for applying thermal and environmental protection coating systems to components. They are widely used to protect the hot structural components of many gas turbine engines that must operate at temperatures approaching their melting point, See S. M. Meier and D. K. Gupta, Trans. of the ASME, 116, 250 (1994), of which is hereby incorporated by reference herein in its entirety. As gas inlet temperatures continue to rise, failure by thermally-induced mechanisms has been avoided by making airfoil components with internal cooling conduits, and injecting compressor discharge air to decrease the component temperature, See A. J. Glassman, Turbine Design and Application, Vol. 3, NASA-SP-290-VOL-3, NASA Lewis Research Center (1975), of which is hereby incorporated by reference herein in its entirety. To maximize engine efficiency, however, it is desirable to minimize the use of this air for cooling purposes. Traditionally, this has been accomplished by designing more efficient cooling geometries within the component and by film cooling of the component surface using drilled holes. These approaches have now matured and alternate strategies that exploit the insulating abilities of thermal barrier coatings (TBC's) are being investigated for the thermal protection of engine components.

The TBC systems currently in use are multilayer systems consisting of an yttria partially-stabilized zirconia (YSZ) top layer that thermally protects the superalloy component, and an underlying MCrAlY (M=Ni, Co) or nickel aluminide bond coat which improves the YSZ adhesion. The YSZ layer has a relatively high thermal expansion coefficient to limit thermally induced strains and a low thermal conductivity resulting in surface temperature reductions of up to 170° C., See W. J. Brindley and R. A. Miller, Advanced Materials and Processes, 29 (1989), of which is hereby incorporated by reference herein in its entirety. This layer is well bonded to a thin (approximately 1 μm) thermally grown (aluminum) oxide (TGO) layer which impedes oxidation and hot corrosion of the underlying component, See R. V. Hillery (ed.), Coatings for High-Temperature structural Materials: Trends and Opportunities, National Academy Press, Washington D.C. (1996), of which is hereby incorporated by reference herein in its entirety. This TGO layer is formed on the surface of the aluminum-rich alloy layer (bond coat). Either a low pressure plasma spray, See C. H. Liebert and R. A. Miller, Ind. Eng. Chem. Prod. Res. Dev., 23, 344 (1984), of which is hereby incorporated by reference herein in its entirety, (LPPS) or pack cementation, See D. Claves and A. Galerie, Journal De Physique IV, C9, 531 (1993), of which is hereby incorporated by reference herein in its entirety, approach is used to apply the bond coat layer. The high temperature oxidization environment present prior to and during deposition leads to growth of a thin TGO layer at the interface between the TBC and the bond coat layer, See O. Unal, J. Am. Ceram. Soc., 77 [4], 984 (1994), of which is hereby incorporated by reference herein in its entirety. The generated YSZ layer consists of a “nontransformable” tetragonal (t′) phase having a complex microstructure consisting of twins and anti-phase boundaries. This microstructure yields a thermomechanically tough coating which has been shown to improve TBC performance by limiting crack propagation in the YSZ layer, See D. Michel, L. Mazerolles and M. Perez Y Jorba, J. of Mat. Sci., 18, 2618 (1983), of which is hereby incorporated by reference herein in its entirety.

To date, the lowest cost TBC's have been applied using the plasma spray (PS) process, such as an air plasma spray (APS) process. The approach employs a plasma or combustion torch to melt and spray deposit YSZ droplets onto airfoil substrates. These deposits contain disc-like pores in the plane of the coating resulting in a YSZ top layer that has an extremely low thermal conductivity. This is due to the high thermal resistance of the pores oriented normal to the heat flow direction. Unfortunately, these layers also have poor spallation resistance, resulting from a combination of the disc-like coating defects and the large thermal expansion mismatch between the YSZ layer and the bond coat, See J. T. DeMasi-Marcin, K. D. Sheffler and S. Bose, J. of Eng. Gas Turbines and Power, 112, 521 (1990), of which is incorporated by reference herein in its entirety. This lack of reliability limits these coatings to component life extension at current operating temperatures (i.e., they cannot be used to increase engine temperature).

More recently, TBC's have been produced by electron beam-physical vapor deposition (EB-PVD). Using this technique the YSZ layer has a columnar microstructure with elongated inter-columnar voids aligned perpendicular to the substrate surface. This structure results in a low in-plane stiffness that limits thermomechanical stresses on heating/cooling and improved spallation resistance compared to the LPPS layers, See T. E. Strangman, Thin Solid Films, 127, 93 (1985), of which is hereby incorporated by reference herein in its entirety. The columns exhibit a tapered shape, growing wider with increased thickness, a faceted surface and a strong {200} crystallographic texture, See U. Schulz, H. Oettel, and W. Bunk, Z. Metallkd., 87, 6 (1996), of which is hereby incorporated by reference herein in its entirety. Failure in these coatings no longer occurs within the YSZ layer but at the TGO/bond coat interface. This failure path appears to result from large stresses within the TGO layer, which increase with oxidation induced layer growth in service, See R. J. Christensen, D. M. Lipkin, D. R. Clarke, and K. Murphy, Appl. Phys. Lett., 69 [24], 3754 (1996) and M. Y. He, A. G. Evans and J. W. Hutchinson, Mat. Sci. Eng., in press (1997), of which are hereby incorporated by reference herein in their entirety. For turbine blade applications, EB-PVD TBC's have the further advantages of limiting the undesirable blocking of air cooling holes during deposition and generating a smoother, more aerodynamic surface, See K. Fritscher et. al., Advanced Aerospace Materials, H. Buhl (ed.), Springer-Verlag, Berlin, Heidelberg (1992) pp. 84-107, of which is hereby incorporated by reference herein in their entirety. However, EB-PVD coatings have a higher thermal conductivity than their LPPS counterparts, See D. J. Wortman, B.A. Nagaraj and E. C. Duderstadt, Mat. Sci. Eng., A121, 443 (1989), of which is hereby incorporated by reference herein in its entirety, and are more costly to apply (due to high equipment costs, deposition efficiencies of about 2-5 percent of the evaporated flux, and relatively slow (approximately 5 micrometers (μm) min⁻¹) deposition rates), See. P. Hancock and M. Malik, Materials for Advanced Power Engineer, Part I, D. Coutsouradis et. al. eds., Kluwer Academic Publishers, Netherlands (1994) pp. 685-704, of which is hereby incorporated by reference herein in its entirety. To make vapor phase deposited TBC's a viable means for increasing engine performance, improved deposition techniques/strategies are needed.

The cost of the EB-PVD coatings can be as much as ten times that of PS coatings. The higher equipment costs of EB-PVD are a result of the high vacuum environment that is necessary during deposition (e.g., typically below 10⁻⁶ Torr), high cost of high power electron beam guns, and sophisticated component manipulation needed to achieve acceptable coatings. The operating pressure defines the vacuum pump requirements with lower pressures generally needing more expensive pumps. The low deposition rate and low materials utilization efficiency (MUE) of EB-PVD is related to the distribution of the vapor flux as it leaves the evaporated source. Generally, the vapor flux spreads out from the source with a distribution described by a cosⁿ θ function (where n=2,3,4 or more, and θ is the angle to the normal axis). The general alignment of the normal axis is referred to herein as the main direction. When relatively long source-to-substrate distances are required (e.g., as in YSZ deposition using EB-PVD where this distance often approaches 50 cm to avoid substrate overheating) deposition efficiency is dramatically decreased to 1-5 percent of the evaporated flux and the deposition rate is proportionally reduced. To overcome the low deposition rate, the evaporation rate from the source materials is raised by increasing the electron beam power. However, this is costly and during YSZ evaporation, increased beam power leads to the production of molten droplets of material rather than atomistic vapor. This produces coating defects, and as a result, other approaches must be used to increase deposition rates. The high cost of deposition also impedes the use of physical vapor deposition methods for the deposition of bond coats.

The low deposition efficiency results from flux spreading beyond the periphery of the sample. One approach to reduce the spread of the flux exploits entrainment of the vapor in a controllable inert (e.g. helium or argon) carrier gas flow, See J. F. Groves and H. N. G. Wadley, Composites B, 28B, 57 (1997), of which is hereby incorporated by reference herein in its entirety. Such an approach is used in electron beam directed vapor deposition (EB-DVD). In this approach, the combination of a continuously operating 60 kV/10 kW axial e-beam gun (modified to function in a low vacuum environment) and an inert carrier gas jet is used. In this system the vaporized material is entrained in the carrier gas jet created using a converging/diverging nozzle configuration and deposited onto the substrate or target at high rate and with a high materials utilization efficiency, See J. F. Groves, Ph. D Thesis, University of Virginia (1998), of which is hereby incorporated by reference herein in its entirety. Preliminary results have shown that YSZ layers having a columnar structure, a low thermal conductivity, the t′ phase structure and a (200) texture can be produced using this technique, See D. D. Hass, Ph. D. Thesis, University of Virginia (2001), of which is hereby incorporated by reference herein in its entirety. Therefore the use of EB-DVD to produce low cost TBC's appears feasible.

There exists a need in the art for, among other things, a cost-effective method to apply high quality TBC top coatings to surfaces. Embodiments of the present invention addresses this need and provides, among other things, how to manipulate the process conditions in a EB-DVD systems to deposit high quality, highly efficient TBC top coats as well as how to deposit high quality TBC top coats onto positions that are that in the line-of-sight (as well as non-line of sight) of the vapor source.

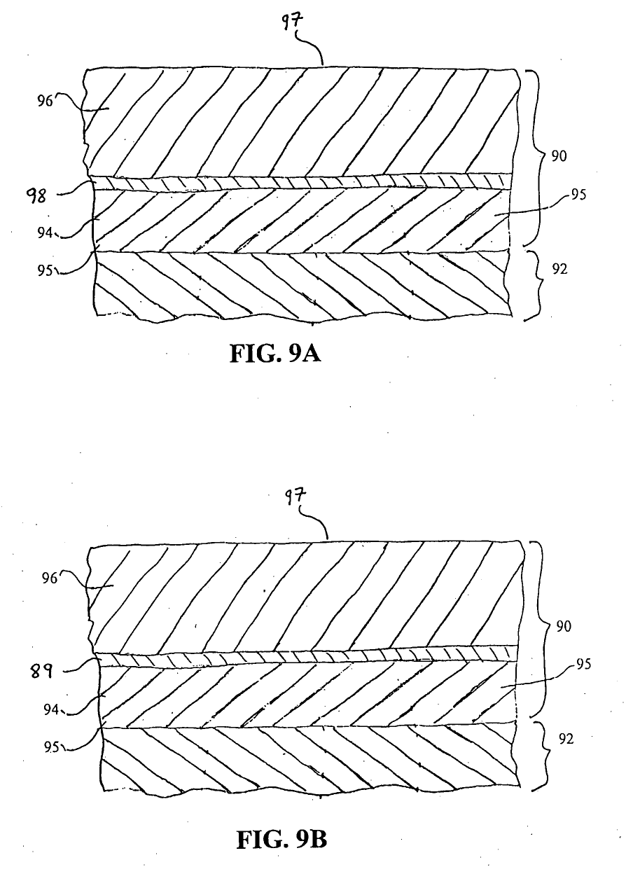

In general, referring to FIGS. 9(A)-9(B), FIGS. 9(A)-9(B) are schematic illustrations of a cross-section partial view of the substrate showing a thermal barrier coating system on the substrate in accordance with exemplary embodiments of this invention. Embodiments of the present invention provide an improved method and system for making a thermal barrier coating which may comprise, among other things, a) a substrate b) a bond coat and c) a ceramic insulating layer (i.e., thermal insulating layer) or layers on top. Turning to FIG. 9(A), FIG. 9(A) schematically represents a TBC system 90 that may be produced by the teachings of embodiments of the present invention. As shown, the coating system 90 includes a ceramic layer (thermal insulating layer) 96 bonded to the substrate 92 with an overlay bond coat 94. Optionally, the bond coat 94 may have ceramic dispersoids 95 of oxygen or other compounds dispersed at least substantially throughout as shown. The substrate 92 (e.g., combustion liner, etc.) is preferably a high-thermal conductivity, high-temperature material, such as copper, nickel or cobalt-base superalloy. The ceramic layer 96 is deposited by the desired deposition technique as taught by embodiments of the present invention. Exemplary high melting temperature material for the ceramic layer (thermal insulating layer) 96 are, but not limited thereto, Zirconium, Hafnium, mullite, alumina, silica, any oxide ceramic, ceria, zirconate, garnet, lanthanum aluminate, titania, any carbide, silicide or combination thereof; or any other desired ceramics or combinations thereof. The ceramic layer 96 is deposited to a thickness that is sufficient to provide the required thermal protection for the underlying substrate 92, generally on the order of about 50 to about 300 micrometers, or as desired or required. As mentioned throughout this document, in some embodiments the surface of the bond coat 94 may exist without an aluminum oxide surface layer (alumina scale) 98, or optionally in other embodiments the surface of the bond coat 94 may have minimal oxidization so as to form an aluminum oxide surface layer (alumina scale) 98 to which the ceramic layer 96 chemically bonds. It should be appreciated, that a TBC system can also be created with heavier layers of aluminum oxide surface layer (alumina scale) 98.

Turning to FIG. 9(B), in an exemplary embodiment, a bond coat 94 may be applied over the substrate 92 or over an intermediate material (such at Ti or desired material) 89.

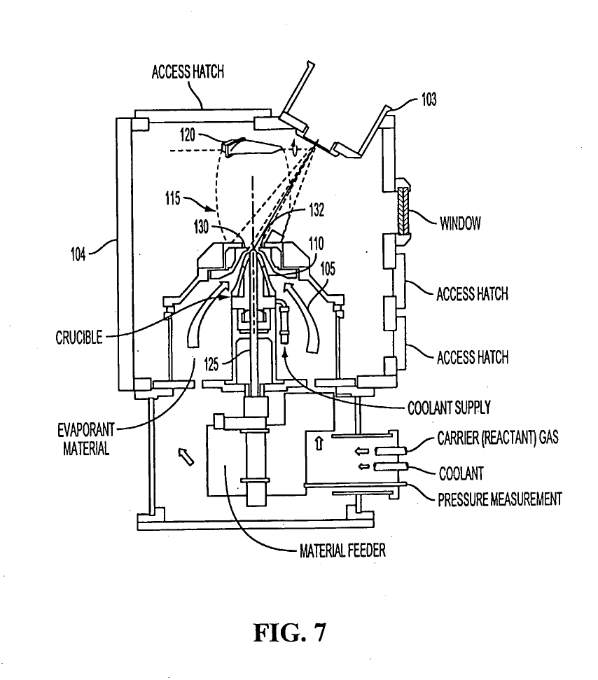

Referring to FIG. 7, FIG. 7 is a schematic illustration of the energetic beam (e.g., e-beam) orientation in a configuration of an embodiment of the present invention DVD processing system. In an embodiment, the carrier gas 105 flows completely or substantially around the crucible 110 so that the vapor flux 115 can be focused onto the substrate 120 located directly above the evaporant source(s) 125. The carrier gas 105 may be adapted to flow substantially parallel with the normal axis, identified as CL, or other direction(s) as desired. Additionally, as will be discussed later herein, the nozzle 130 has a nozzle gap or opening 132, through which the carrier gas 105 flows, and may be designed such that a more optimal carrier gas speed distribution for focusing the vapor 115 is produced. Also shown is the electron energetic beam 103 (e.g., beam gun) and vacuum chamber 104.

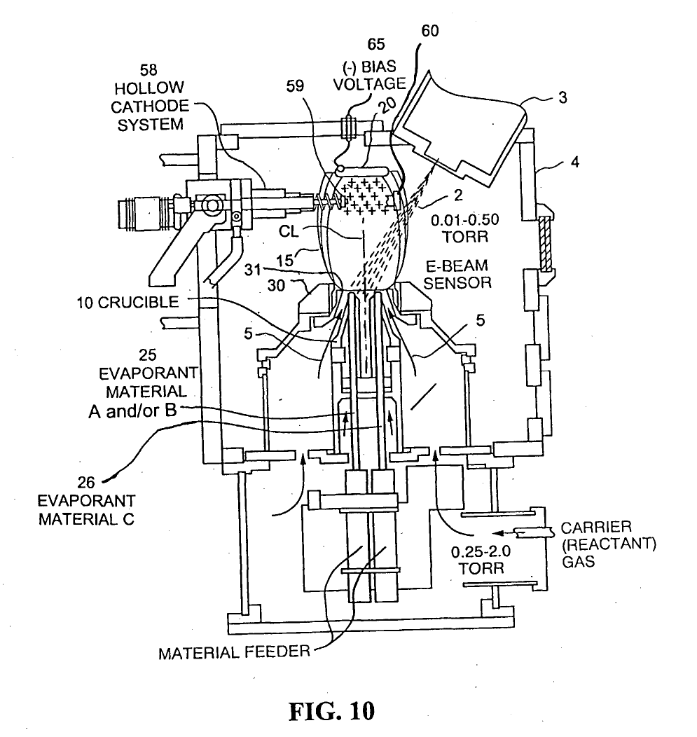

Referring to FIG. 10, FIG. 10 is a schematic illustration of the directed vapor deposition (DVD) process. In the DVD, the carrier gas stream 5 is created by a rarefied, inert gas supersonic expansion through a nozzle 30. The speed and flux of the atoms entering the chamber 4, the nozzle parameters, and the operating chamber pressure can all be varied leading to a wide range of accessible processing conditions. As part of the process the supersonic carrier gas stream may be maintained by achieving a high upstream pressure (i.e. the gas pressure prior to its entrance into the processing chamber), Pᵤ, and a lower chamber pressure, Pₒ. The ratio of the upstream to downstream pressure along with the size and shape of the nozzle opening 31 controls the speed of the gas entering the chamber 4. The carrier gas molecular weight (compared to that of the vapor) and the carrier gas speed controls its effectiveness in redirecting the vapor atoms via binary collisions towards the substrate 20. As will be discussed later, alternative embodiments of the present invention process will provide other capabilities to evaporate from two or more individual source rods and the ability to ionize the evaporated flux using hollow cathode plasma activation.

Still referring to FIG. 10, the aforementioned DVD process as schematically shown in FIG. 10, improves the deposition efficiency, increases the deposition rate, optionally provides coating dispersoids, and enhances the coating uniformity, as well as other aspects as discussed throughout this document. As will be discussed later, the hollow cathode system 58 is optional based on desired operations. In an embodiment, the carrier gas 5 is realigned so that it is substantially in-line with the crucible 10. In this alignment, the carrier gas flow is placed completely or substantially around the crucible 10 so that the vapor flux 15 no longer has to be turned 90 degrees towards the substrate 20, but rather can be simply focused onto the substrate located directly above the evaporant source 25 for material A and/or B and evaporant source 26 for material C. For example, material A, B and/or C may include Zirconium, Hafnium, mullite, alumina, silica, any oxide ceramic, ceria, zirconate, garnet, lanthanum aluminate, titania, any carbide, silicide or combination thereof; as well as other ceramic materials or combinations thereof. It should be appreciated that as discussed throughout this document, materials A, B and/or C may have substantially the same chemical composition relative to one another; or alternatively may have different chemical compositions relative to one another.

Further, it should be appreciated that as discussed throughout out this document, the size or area of the evaporant source may vary as desired or required. Exemplary ranges may include, but not limited thereto, the evaporant source having a diameter in the range of about 0.1 inch to about 10 inch or about 0.5 inch to about 1 inch. Again, the size and area may be larger or smaller. For example, exemplary surface areas may include ranges from about 0.007 to about 80 square inches or about 0.19 to about 0.8 square inches. The evaporant surface areas may be larger or smaller depending on the coating/deposition process requirements.

The carrier gas 5 flows substantially parallel with the normal axis, identified as CL. Additionally, as will be discussed later herein, the nozzle 30 has a nozzle gap or opening 32, through which carrier gas 5 flows, is designed such that a more optimal carrier gas speed distribution for focusing the vapor 15 is produced. Also shown is the energetic beam source 3 (as discussed throughout this document), which should be appreciated to take a variety of forms as such as, but not limited thereto, electron beam source, laser source, heat source, ion bombardment source, highly focused incoherent light source, microwave, radio frequency, EMF, or combination thereof, or any energetic beams that break chemical bonds.

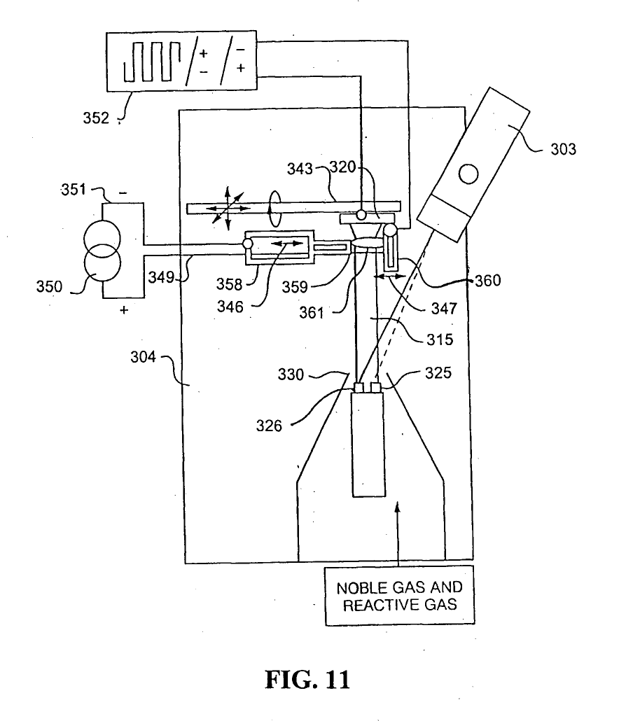

Turning to FIG. 11, the major components of the present invention DVD apparauts including a hollow cathode arc plasma activation and substrate bias supply as schematically shown. The present invention DVD system embodiment comprises a vacuum chamber 304, a first rod feed evaporator 325 (evaporant A & B) and second rod evaporator 326 (evaporant C) that are placed and heated up to evaporation temperature of evaporant by the electron-beam of an electron gun 303 and provides the vapor for coating of substrates 320. Vaporized evaporant is entrained in the supersonic gas and vapor stream 315 formed by the nozzle 330. The substrate(s) 320 are fixed at a substrate holder 343 which enables shift of the substrate in any independent direction and to be swiveled. For example, the translation motion in the horizontal plan allows the exposed surface areas of the substrate to the vapor stream for defined dwelling times and control of the local coating thickness. The vertical motion can be used to keep constant the distance between plasma and surface for curved substrates. Swivel motion, in coordination with the translation motions, can be used to enable the coating of complete three-dimensional parts or can be used also to change the incidence angle of the vapor particles in the course of layer coating in a defined way for getting distinct layer properties. The hollow cathode (arc source) 358 is placed laterally below substrate holder 343 with a short distance between the cathode orifice 359 and the gas and vapor stream 315. The anode 360 is arranged opposite the cathode orifice 359 (i.e., on an approximate distant side of the stream 315) so that the fast electrons and the plasma discharge 361 crosses the gas and vapor stream 315. The fixtures for the cathode 346 and for the anode 347 provide the ability to adjust the distance of the cathode 358 and the anode 360, thereby influencing the diameter and the shape of gas and vapor stream 315.

The plasma discharge 361 is in close proximity (arranged with short distance) to the surface of the substrate 320 enabling close contact between dense plasma and the substrate surface to be coated. In the vicinity of the evaporation electron-beam from the electron gun 303, the anode power line 349 from the power generator 350 to the anode 360 is arranged closely and in parallel with both the plasma discharge 359 and the cathode power line 351, which runs from the cathode to the power generator 350. Between the substrate 320 and the anode 360, a bias generator 352 is applied that allows for generation of a positive, a negative or a periodically alternating voltage between the substrate 320 and the plasma 361.

In all such cases, the ability to deposit compositionally controlled coatings efficiently, uniformly, at a high rate, with high part throughput, and in a cost-effective manner, among other things, is desired. According to the design criteria discussed throughout, some illustrative examples of deposition systems and methods that may be implemented with some embodiments of the present invention are provided in the following applications and patents and are co-assigned to the present assignee 1) U.S. Pat. No. 5,534,314, filed Aug. 31, 1994, entitled “Directed Vapor Deposition of Electron Beam Evaporant,” 2) U.S. Pat. No. 5,736,073, filed Jul. 8, 1996, entitled “Production of Nanometer Particles by Directed Vapor Deposition of Electron Beam Evaporant,” 3) U.S. Pat. No. 6,478,931 B1, filed Aug. 7, 2000, entitled “Apparatus and Method for Intra-layer Modulation of the Material Deposition and Assist Beam and the Multilayer Structure Produced There from,” and corresponding Divisional U.S. application Ser. No. 10/246,018, filed Sep. 18, 2002, 4) International Application No. PCT/US01/16693, filed May 23, 2001 entitled “A Process and Apparatus for Plasma Activated Deposition in a Vacuum,” and corresponding U.S. application Ser. No. 10/297,347, filed Nov. 11, 2002, 5) International Application No. PCT/US02/13639, filed Apr. 30, 2002, and corresponding U.S. application Ser. No. 10/476,309, filed Oct. 29, 2003 entitled “Method and Apparatus for Efficient Application of Substrate Coating,” 6) International Application No. PCT/US2003/037485, filed Nov. 21, 2003 entitled “Bond Coat for a Thermal Barrier Coating System and Related Method thereof,” 7) International Application No. PCT/US2003/036035, filed. Nov. 12, 2003, entitled “Extremely Strain Tolerant Thermal Protection Coating and Related Method and Apparatus thereof,” 8) International Application No. PCT/US03/12920, filed Apr. 25, 2003, entitled “Apparatus and Method for High Rate Uniform Coating, Including Non-line of Sight,” 9) International Application No. PCT/US2003/02311, filed Jul. 24, 2003, entitled “Method and Apparatus for Dispersion Strengthened Bondcoats for Thermal Barrier Coatings,” 10) International Application No. PCT/US02/28654, filed Sep. 10, 2002 entitled “Method and Apparatus for Application of Metallic Alloy Coatings” and corresponding U.S. application Ser. No. 10/489,090, filed Mar. 9, 2004, entitled “Method and Apparatus for Application of Metallic Alloy Coatings;” of which all of these patents and applications are hereby incorporated by reference herein in their entirety.

Other U.S. Patents, Applications, and Publications that are hereby incorporated by reference herein in their entirety include the following:
1. U.S. Publication No. 2003/0180571 A1 to Singh
2. U.S. Publication No. 2003/0138660 A1 to Darolia et al.
3. U.S. Publication No. 2003/0129378 A1 to Movchan et al.
4. U.S. Publication No. 2003/0129316 A1 to Darolia et al.
5. U.S. Publication No. 2003/0118874 A1 to Murphy
6. U.S. Publication No. 2002/0110698 A1 Singh
7. U.S. Pat. No. 6,630,199 B1 to Austin et al.
8. U.S. Pat. No. 6,585,878 B2 to Stangman et al.
9. U.S. Pat. No. 6,528,118 B2 to Lee et al.
10. U.S. Pat. No. 6,485,845 B1 to Wustman et al.
11. U.S. Pat. No. 6,461,746 B1 to Darolia et al.
12. U.S. Pat. No. 6,455,167 B1 to Rigney et al.
13. U.S. Pat. No. 6,444,331 B2 to Ritter et al.
14. U.S. Pat. No. 6,440,496 B1 to Gupta et al.
15. U.S. Pat. No. 6,436,473 B1 to Darolia et al.
16. U.S. Pat. No. 6,395,343 B1 to Strangman
17. U.S. Pat. No. 6,306,524 B1 to Spitsberg et al.
18. U.S. Pat. No. 6,291,084 B1 to Darolia et al.
19. U.S. Pat. No. 6,273,678 B1 to Darolia
20. U.S. Pat. No. 6,258,467 B1 to Subramanian
21. U.S. Pat. No. 6,255,001 B1 to Darolia
22. U.S. Pat. No. 6,203,927 B1 to Subramanian et al.
23. U.S. Pat. No. 6,168,874 B1 to Gupta et al.
24. U.S. Pat. No. 6,153,313 to Rigney et al.
25. U.S. Pat. No. 6,123,997 to Schaeffer et al.
26. U.S. Pat. No. 6,096,381 to Zheng
27. U.S. Pat. No. 5,712,050 to Goldman et al
28. U.S. Pat. No. 5,498,484 to Duderstadt
29. U.S. Pat. No. 5,419,971 to Skelly et al.
30. U.S. Pat. No. 4,321,311 to Strangman
31. U.S. Patent Publication No. 2002/0152961 A1 to Burns
32. U.S. Pat. No. 6,485,844 B1 to Strangman et al.
33. U.S. Pat. No. 6,458,473 B1 to Conner et al.
34. U.S. Pat. No. 6,477,932 B1 to O'Hara et al.
35. U.S. Pat. No. 6,255,001 B1 to Darolia
36. U.S. Pat. No. 6,123,997 to Schaeffer et al.

### Highly Efficient Top Coats

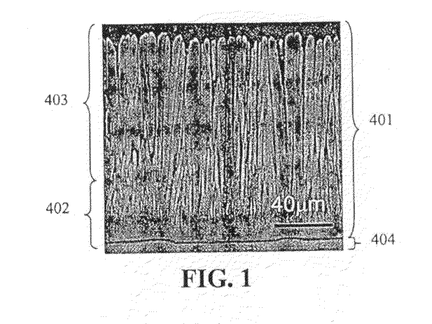

Referring to FIG. 1, FIG. 1 provides a micrograph depiction showing a YSZ top coat 401 located above another layer (for example, bond coat 404) that is applied using EB-PVD. The thermal protection of the top coats of thermal barrier coating system produced by electron beam—physical vapor deposition (EB-PVD) has a relatively high density (80 to 95% of the bulk value for YSZ), columnar morphology. At the bottom of the YSZ coating 401—generally referred to the approximate area designated as 402—where deposition first occurs many, randomly orientated grains are formed. Columnar structures—generally referred to the approximate area designated as 403—evolve with a tapered shape, a (200) texture and a faceted surface. The columns contain porosity. Vapor deposited coatings with this structure are effective top coats that yield a long lifetime, good erosion resistance and adequately low thermal conductivity.

Thermal barrier coatings can also be produced using a directed vapor deposition approach. In this approach the evaporant is entrained in a gas jet and transported to the substrate where it is deposited. This approach can be used to create top coats that are very similar to those produced using EB-PVD (but in a much more economical manner) as well as top coats that are very different from conventional coatings. Both may have utility for engine component protection, among other desired or required purposes.

The morphology of DVD deposited top coats is strongly dependent on the process conditions used. If the rate of evaporation is sufficiently low, and the atoms/molecules of the gas high enough velocity to entrain, dilute and transport the vapor to the substrate an atomic/molecular flux is presented to the component for deposition. The angle of incidence this flux makes with the substrate is broadly distributed. The width of the distribution is controllable by adjusting the flow conditions used to create the gas jet. Changing the process conditions to cause high rate evaporation, low gas jet atom velocity and high vapor concentration in the jet results in gas phase cluster formation and the presentation of mixed atomic/molecular+cluster flux for deposition on the surface of the component. Conditions that limit the vapor phase nucleation and growth of clusters and the divergence of the vapor incidence angle distribution from EB-PVD conditions allow top coats similar to those made by EB-PVD to be deposited. In DVD this can be done with a much higher deposition efficiency that enables a reduced evaporation rate to meet a target deposition rate and results in a more economical utilization of the source material.

Critical process conditions for the deposition of top coats include: substrate temperature, chamber pressure, pressure ratio, evaporation rate, substrate rotation rate. For each parameter a process range can be defined, for example, over which conventional coatings can be applied.
a) Substrate temperature: The maximum temperature is defined by the melting point of the substrate (or its maximum exposure temperature). The minimum temperature is limited by the coating density. This minimum temperature is the same as the EB-PVD process (˜900° C.). As the chamber pressure and evaporation rate increase the minimum allowable temperature will become gradually higher.
b) Chamber Pressure: The maximum chamber pressure is defined as the pressure at which the vapor phase nucleation and growth of clusters and the divergence in the vapor incident angle distribution deviates significantly from EB-PVD conditions. From DSMC simulations and experimental work this is typically between 0.01 Torr and 1.0 Torr. Higher pressures can be allowed as the substrate temperature is increased. The minimum chamber pressure is defined by the pressure that results in a mean free path that is greater than the source-to-substrate distance. At this chamber pressure the gas jet will not affect the vapor flux. For a source-to-substrate distance of 20 cm this value is 0.0085 Pa.
c) Pressure Ratio: The minimum pressure ratio must be greater than 1.0 to allow carrier gas flow towards the substrate. This is often higher (>2.2). Increased pressure ratios improve the process efficiency and limit the formation of vapor phase clusters. The maximum pressure ratio is controlled by the pumping rate of the chamber pumps and the area of the gas jet nozzle opening.
d) Evaporation Rate: This should be as high as possible. The maximum is defined by the formation of vapor phase clusters due to the increased the vapor density.
e) Substrate Rotation Rate: The minimum rotation rate is 1revolution during the time required to coat a part. No maximum is defined.

The combination of these limitations can be used to define a process space that allows the deposition of coatings having similar structures as EB-PVD. This process space (space A) is most conveniently displayed with a series of three axes plots, FIG. 1. A table of the process ranges is also given, Table 1. Table 1 provides the process ranges of depositing a TBC top coat with a coating morphology similar to EB-PVD.

TABLE 1

| Parameter | Minimum | Maximum |
|---|---|---|
| Chamber | 0.1 Pa | 20 Pa |
| Pressure | | |
| Pressure Ratio | 1.01 | 1000 |
| Substrate | 900° C. | 1250° C. |
| Temperature | | |
| Rotation Rate | 0 | Infinite |
| Evaporation Rate | 0.1 g/min | 100.0 g./min. |
| (0.5″ diameter | | |
| source) | | |

It should be appreciated that a variety of process conditions may be utilized in addition to Table 1 listed above. For example, but not limited thereto, the substrate temperature may be below, equal to, or greater than a given melting point of such substrate. The process ranges and variations of Table 1 would be suitable, for example but not limited thereto, producing microstructures. The evaporation rate may be as broad as about 0.00001 g/min to about 100,000 g/min, or as required or desired. Further, it should be appreciated that, in addition to the conditions listed in the table above, the chamber pressure, pressure ratio, and rotation rate (including pattern of movement or lack of rotation/movement) may varied as desired or required.

### NLOS TBC Top Coat Deposition

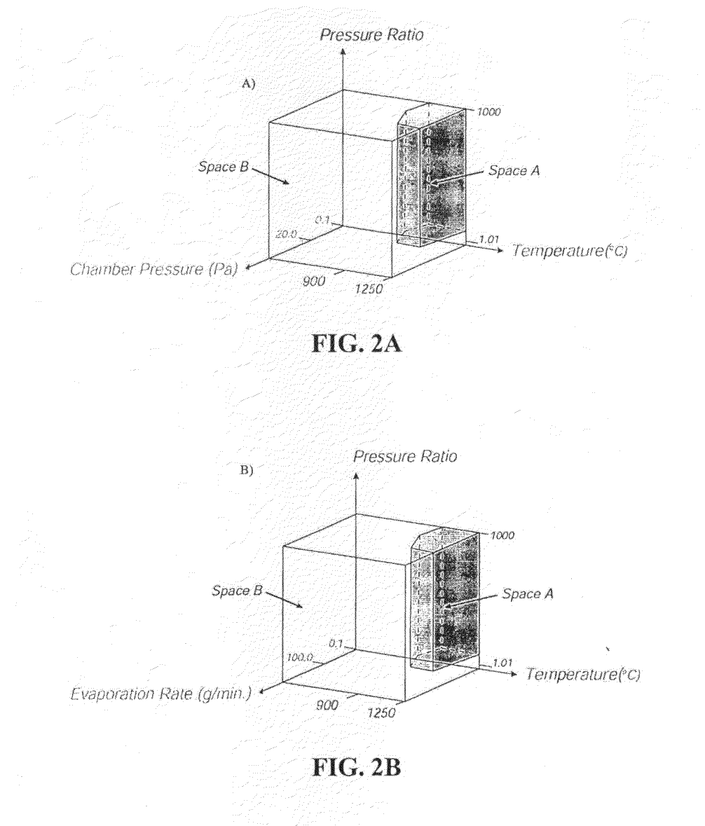

Next, referring to FIGS. 2(A)-(E), there is provided a graphical representation of three dimension plots a) Temperature b) Evaporation Rate and c) Chamber Pressure that define the process space for the deposition of TBC topcoats having a similar morphology to that of EB-PVD deposited top coats. The process space for Directed Vapor Deposition is much larger than that defined above as defined in Table 1. The space outside that defined in section 1 (space B) can also be used, however, to create top coats. The morphology of top coats produced in this way is different than that of conventional layers. In these cases, the vapor incidence angle is altered by scattering between and vapor atoms and the gas jet atoms so that it is significantly different to that of in space A. In addition, elevated chamber pressures, low pressure ratios and high evaporation rates will also increase the probability of vapor phase cluster formation. The result of cluster formation is a change in the coating growth mechanism and typically an increase in the pore volume fraction. This may result in long cyclic oxidation lifetimes, but the increased porosity is expected to limit the erosion resistance of these layers. This process space is also found to be useful for deposited top-coats onto non line-of-sight regions (NLOS) of the substrate. Table 2, below provides the available process conditions for directed vapor deposition

TABLE 2

| | Minimum | Maximum |
|---|---|---|
| Chamber Pressure | 1 × 10 − 4 Pa | 150 Pa |
| Pressure Ratio | 1.01 | 10000000 |
| Evaporation Rate | 0.00001 g/min. | 100000 g/min. |
| Temperature | 25° C. | 1250° C. |
| Rotation Rate | No rotation | Infinite |

It should be appreciated that a variety of process conditions may be utilized in addition to Table 2 listed above. For example, but not limited thereto, the substrate temperature may be below, equal to, or greater than a given melting point of such substrate. The evaporation rate may be as narrower, such as about 0.1 g/min to about 100 g/min, or as required or desired. Further, it should be appreciated that, in addition to the conditions listed in the table above, the chamber pressure, pressure ratio, and rotation rate (including pattern of movement or lack of rotation/movement) may varied as desired or required.

Several approaches can be used to increase the density of coatings deposited in space B, such as but not limited thereto, a) increased substrate temperatures during deposition; and/or b) use of plasma activation to increase the impact energy of the incident vapor atoms.

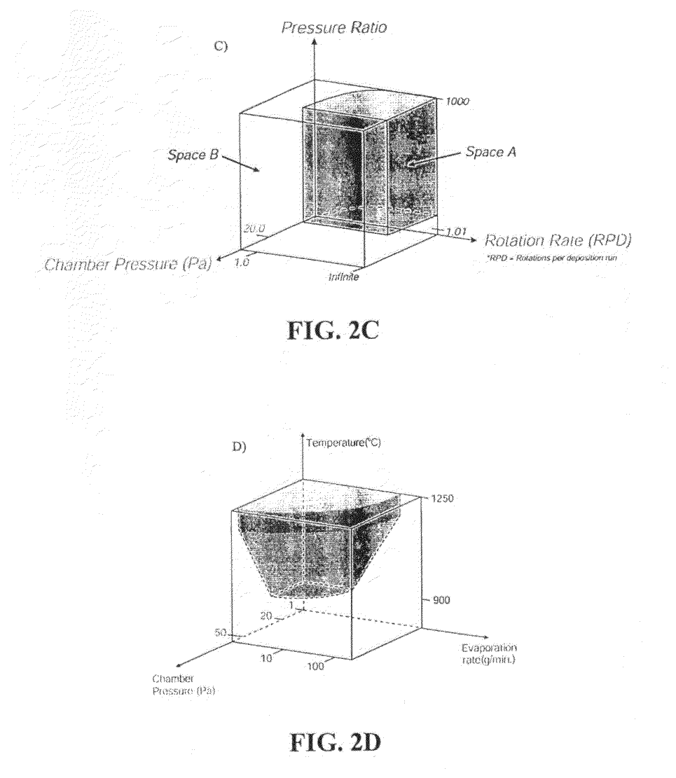

Any temperature increase may be limited by the melting point of the substrate. However, plasma activation allows denser coatings even at quite low substrate temperatures. This enables a coating with the standard density to be deposited at higher pressures than without the plasma, see for example FIG. 3. FIG. 3 is a graphical representation plotting the angle of incidence distribution for the cases of DVD and EB-PVD.

### Deposition Efficiency

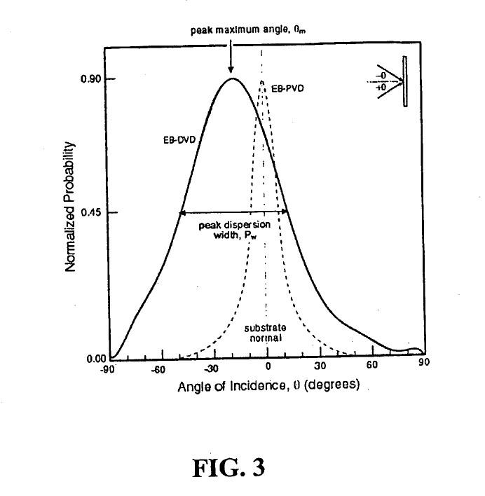

As a reference, see commonly assigned International Application Nos. PCT/US03/12920, filed Apr. 25, 2003, entitled “Apparatus and Method for Uniform Line of Sight and Non-line of Sight Coating at High Rate and PCT/US02/13639, filed Apr. 30, 2002 entitled “Method and Apparatus for Efficient Application of Substrate Coating and corresponding U.S. application Ser. No. 10/476,309, filed Oct. 29, 2003 entitled “Method and Apparatus for Efficient Application of Substrate Coating,” of which these three applications are hereby incorporated by reference herein in their entirety. When using the process conditions in space A, the deposition efficiency is controlled by the area of the evaporated flux near the substrate with respect to the area of the substrate and the interaction of the gas jet with the substrate. The gas jet substrate interaction should be limited to achieve the highest deposition efficiencies. For a given chamber pressure, the area of the evaporated flux is decreased by increasing the pressure ratio. As the pressure is decreased the pressure ratio must be steadily increased to provide the same “focus” of the flux. However, as the pressure is reduced the interaction between the gas jet and the substrate is also limited. These conditions will result in very high deposition efficiencies, as shown in FIG. 4. FIG. 4(A) is a photographic depiction of a DVD system that has the ability to combine focused evaporation with plasma activation for rapid, efficient deposition of various crystal structures. FIG. 4(B) is a graphical depiction of X-ray scans that reveal the effect of plasma activation upon atomic structure.

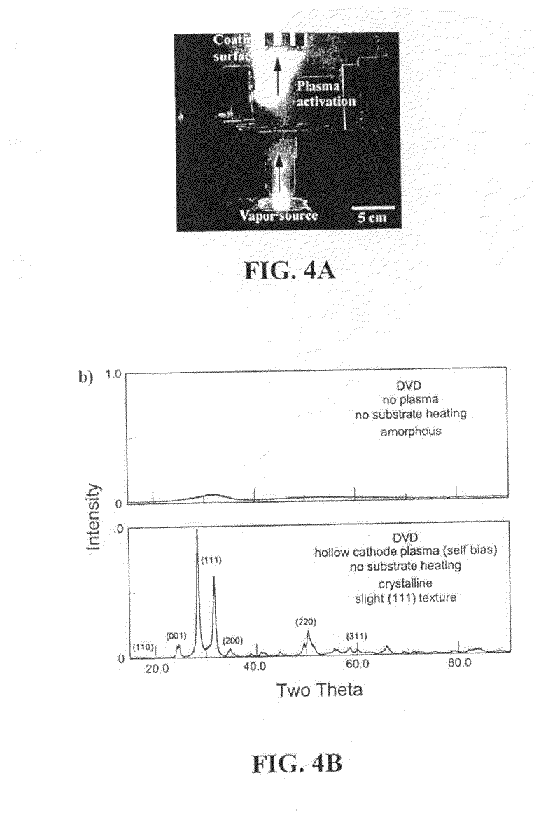

Referring to FIG. 5, FIG. 5 is a graphical depiction from experimental and direct simulation Monte Carlo data showing the effect of chamber pressure and pressure ratio on the deposition efficiency of copper deposited onto a 5.08 cm diameter disc located 10 cm from the evaporation source.

In space B the situation is more complicated. The deposition efficiency is not only controlled by the area of the evaporated flux near the substrate with respect to the area of the substrate and the interaction of the gas jet with the substrate but also by the degree of non line-of-sight coating that occurs. The highest process efficiency in this case is when high chamber pressures and low pressure ratios are employed. This results in a short mean free path and a moderate gas jet velocity. The result is a moderately focused vapor flux, a limited interaction between the gas jet and the substrate and a high degree of non line-of-sight (NLOS) coating.

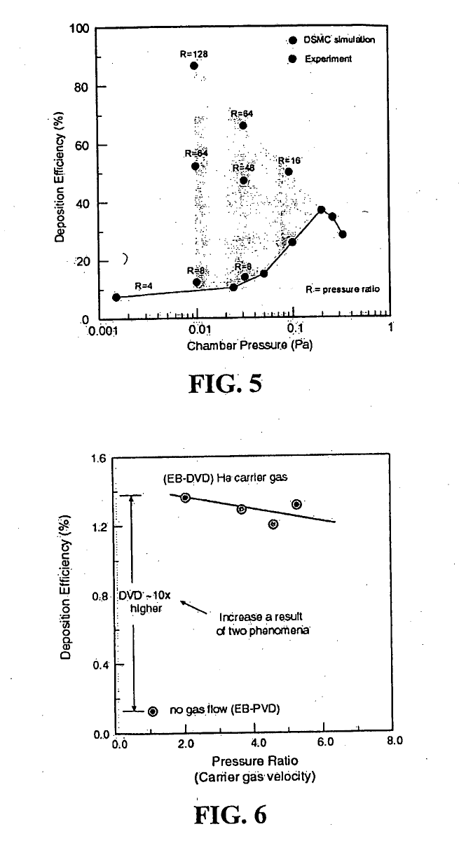

Referring to FIG. 6, FIG. 6 is a graphical depiction of deposition efficiency of Aluminum deposited onto a 380 micron diameter fiber located 15 cm from the vapor source. A chamber pressure of 16 Pa is used in the EB-DVD cases. The use of a gas jet results in a more focused flux that enables a 10× increase in efficiency over EB-PVD. However, the deposition efficiency is relatively unaffected by increasing the pressure ratio because although increasing the pressure ration decreases the area of the evaporated flux (i.e. more focused flux) it also decreases the amount of Non-line of sight (NLOS) coating that occurs.

Plasma activation of the vapor and gas atoms alters their collisional cross section. This in turn alters their mean free path and thus, the degree of non-line-of-sight coating that occurs during deposition. Increased ionization of the flux will therefore result in NLOS coating in a similar way as increasing the chamber pressure. In addition, the ability to attract the ionized flux to the substrate by applying a bias will also increase the degree of NLOS coating.

### Substrate Heating

The component onto which a TBC is applied must be heated during the deposition of conventionally applied top coats using EB-PVD. This is achieved by placing the part in a pre-heating furnace, moving the part into a deposition chamber and then maintaining the part temperature by taking advantage of the radiant heat from the evaporating source. Thus, in the case of EB-PVD the substrate heating is coupled to the YSZ evaporation process.

When using EB-DVD the process is somewhat different. A pre-heater may still be used to initially heat the component, however, the smaller source rod diameter used (in this case 0.5″) limits the fraction of electron beam power that is lost to the environment. Thus, additional measures are required to maintain the part temperature or reduce the requirement of high substrate temperatures.

To account for the reduced heat from the source during deposition an additional component heater may also be employed. This may use resistance, radiant or electron beam heating to maintain the proper component temperature. Another approach would be to construct the area around the nozzle and crucible out of zirconia. Then by overscanning the electron beam onto this area during deposition this area could be made to radiate addition heat. These approaches have the advantage of decoupling the evaporation process from the heating process. The addition of a second electron beam gun for component heating is also possible.

The required component temperatures can also be reduced by using plasma activation to increase the kinetic energy of the depositing atoms.

### Source Rod

Another important aspect of depositing TBC's using EB-PVD is the ability to uniformly evaporate low thermal conductivity ceramic materials at high rate without any “spitting” from the melt pool or the formation of protrusions from the melt pool that can lead to “spitting”. The protrusions can occur quickly when small source sizes are employed, thus a systematic means for preventing their occurrence is required. An approach used in DVD is to evaporate with an electron beam gun angled 35° from the normal to the source, FIG. 5, and rotating the source as it is fed up into the crucible. The rotation requires that any protrusions are pass into the electron beam to a melted before they can grow to an appreciable size. Referring to FIG. 7, FIG. 7 is a schematic illustration of the energetic beam (e.g., e-beam or the like) orientation in one configuration of a DVD processing system.

### Pre-Treatment of the Substrate

The substrate material that consists of a superalloy and a bondcoat may be heat treated prior to the deposition of the YSZ. This can be preformed in air and in a slight vacuum. An example of an air heat treatment is 1120° C. for 1 hour. An example of a vacuum heat treatment is 1120° C. for 8 hours at a vacuum pressure of 10⁻⁴ Pa.

An ionized oxygen flux can also be created using the plasma activation system on the DVD. This can be used to form an alpha alumina layer on the bond coat prior to deposition.

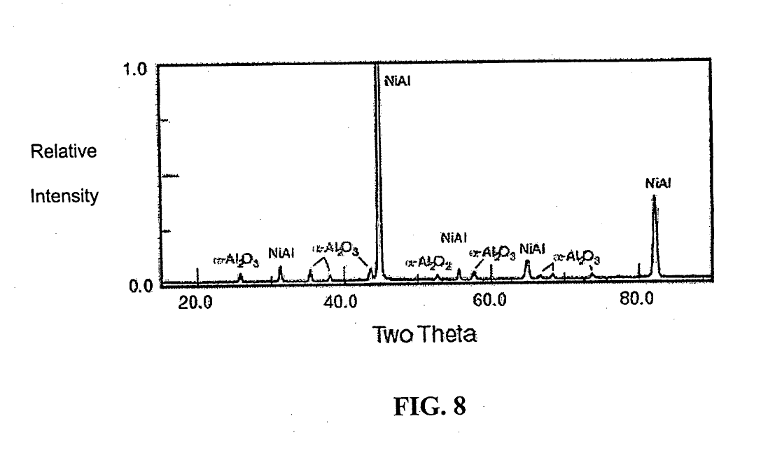

Referring to FIG. 8, FIG. 8 is a graphical depiction of an XRD pattern showing the formation of an alpha alumina layer on a nickel aluminide bond coat using a vacuum heat treatment.

### Exemplary Process Ranges

### Highly Efficient TBC Deposition

Based on the above information and that disclosed previously, an exemplary process range can be defined for the deposition of thermal barrier coatings using a directed vapor deposition (DVD) process. The process includes a method for evaporating a source rod (any material suitable for a TBC top coat can be used (examples are Yttria Stabilized Zirconia and Gadolinium Zirconate), a method for producing a gas jet, a method for heating the component having the proper pre-treatment and a method for translating and rotating a component. The process ranges given in Table 3 are desired for depositing a TBC top coat in a highly efficient manner with a coating morphology similar to EB-PVD.

TABLE 3

| Parameter | Minimum | Maximum |
|---|---|---|
| Chamber | 1 Pa | 20 Pa |
| Pressure | | |
| Pressure Ratio | 11 | 1000 |
| Substrate | 900° C. | 1250° C. |
| Temperature | | |
| Rotation Rate | 0 | Infinite |
| Evaporation Rate | 0.1 g/min | 100.0 g./min. |
| (0.5″ diameter | | |
| source) | | |

It should be appreciated that a variety of process conditions may be utilized in addition to Table 3 listed above. For example, but not limited thereto, the substrate temperature may be below, equal to, or greater than a given melting point of such substrate. The process ranges and variations of Table 3 would be suitable, for example but not limited thereto, high deposition efficiency. The evaporation rate may be as broad as about 0.00001 g/min to about 100,000 g/min, or as required or desired. Further, it should be appreciated that, in addition to the conditions listed in the table above, the chamber pressure, pressure ratio, and rotation rate (including pattern of movement or lack of rotation/movement) may varied as desired or required.

### NLOS TBC Deposition

Exemplary process conditions for NLOS coating are summarized in Table 4 below.

TABLE 4

| Parameter | Minimum | Maximum |
|---|---|---|
| Chamber | 5 Pa | 50 Pa |
| Pressure | | |
| Pressure Ratio | 1 | 100 |
| Substrate | 900° C. | 1250° C. |
| Temperature | | |
| Rotation Rate | 0 | Infinite |
| Evaporation Rate | 0.1 g/min | 100.0 g./min. |
| (0.5″ diameter | | |
| source) | | |

It should be appreciated that a variety of process conditions may be utilized in addition to Table 4 listed above. For example, but not limited thereto, the substrate temperature may be below, equal to, or greater than approximately room temperature (room temperature being defined approximately 15° C. to about 20° C.). The substrate temperatures may be greater than or less than as listed in the table. The temperatures may be as desired or required. Some non-limiting ranges are about 300 to about 1,250° C., 600 to about 1,250, and 900 to about 1,250° C. or greater. The process ranges and variations of Table 1 would be suitable, for example but not limited thereto, producing microstructures. The evaporation rate may be as broad as about 0.00001 g/min to about 100,000 g/min, or as required or desired. Further, it should be appreciated that, in addition to the conditions listed in the table above, the chamber pressure, pressure ratio, and rotation rate (including pattern of movement or lack of rotation/movement) may varied as desired or required.

The following references are hereby incorporated by reference herein in their entirety:
1. D. D. Hass, Ph. D. Dissertation, University of Virginia (2000)
2. D. D. Hass, P. A. Parrish and H. N. G. Wadley, J. Vac. Sci. Technol. A 16(6) (1998) p. 3396.
3. D. D. Hass, H. N. G. Wadley “Directed Vapor Deposition of Thermal Barrier Coatings” (1998)
4. D. D. Hass, A. J. Slifka, H. N. G. Wadley, Acta. Mater., 49 (2001) 973.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of the appended claims. For example, regardless of the content of any portion (e.g., title, section, abstract, drawing figure, etc.) of this application, unless clearly specified to the contrary, there is no requirement for any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Accordingly, the descriptions and drawings are to be regarded as illustrative in nature, and not as restrictive.

The invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims rather than by the foregoing description, and all changes which come within the meaning and range of equivalency of the claims are therefore intended to be embraced herein.

We claim:

1. A method for forming a thermal barrier coating system in communication with at least a portion of at least one substrate, the method comprising:
presenting said at least one substrate to a chamber; wherein said chamber has a down stream pressure, P_{c}, with an operating range from about 0.0001 Pa to about 150 Pa;
depositing a bond coat on at least a portion of at least one said substrate;
presenting at least one evaporant source to said chamber;
presenting at least one carrier gas stream to said chamber, wherein said at least one carrier gas stream is generated from at least one nozzle;
impinging at least one said evaporant source with at least one energetic beam in said chamber to generate an evaporated vapor flux in a main direction respective for any of said evaporant sources impinged by said energetic beam, said at least one evaporant source is disposed in said nozzle;
said at least one carrier gas stream has a pressure ratio in the operating range from about 1.01 to about 10,000,000;
said substrate having a temperature approximately equal to or greater than a melting point of said substrate;
said at least one evaporant source generates said evaporated vapor flux and an evaporation rate in the range of about 0.00001 g/min to about 100,000 g/min; and
deflecting at least one of said generated evaporated vapor flux by at least one of said carrier gas stream, wherein said carrier gas stream is essentially parallel to the main direction and substantially surrounds said evaporated flux, wherein said evaporated vapor flux at least partially coats at least one said substrate.

2. The method of claim 1, wherein said substrate having a temperature in the range of about 25° C. to about 1,250° C.

3. The method of claim 1, wherein:
said down stream pressure, P_{c}, has an operating range from about 0.1 Pa to about 20 Pa;
said at least one carrier gas stream has a pressure ratio in the operating range from about 1.01 to about 1,000; and
said substrate having a temperature approximately equal to or greater than a melting point of said substrate.

4. The method of claim 3, wherein said substrate having a temperature in the range of about 900° C. to about 1,250° C.

5. The method of claim 1, wherein:
said down stream pressure, P_{c}, has an operating range from about 1 Pa to about 20 Pa;
said at least one carrier gas stream has a pressure ratio in the operating range from about 11 to about 1,000; and
said substrate having a temperature approximately equal to or greater than a melting point of said substrate.

6. The method of claim 5, wherein said substrate having a temperature in the range of about 900° C. to about 1,250° C.

7. The method of any one of claims 1, 2, 3, 4, 5 and 6, wherein said at least one substrate is held stationary during the deposition process.

8. The method of any one of claims 1, 2, 3, 4, 5 and 6, wherein said at least one substrate is moved during at least a portion of the deposition process.

9. The method of claim 8, wherein the movement comprises at least a partial rotation or multiple rotations.

10. The method of any one of claims 1, 2, 3, 4, 5 and 6, wherein said at least one evaporant source has a diameter in the range of about 0.1 inch to about 10 inch.

11. The method of claim 10, wherein said at least one evaporant source has a diameter in the range of about 0.5 inch to about 1 inch.

12. The method of anyone of claims 3 and 4, wherein said evaporation rate in the range of about 0.1 g/min to about 100 g/min.

13. The method of any one of claims 12, wherein said at least one evaporant source has a diameter in the range of about 0.1 inch to about 10 inch.

14. The method of claim 13, wherein said at least one evaporant source has a diameter in the range of about 0.5 inch to about 1 inch.

15. The method of anyone of claims 5 and 6, wherein said evaporation rate in the range of about 0.1 g/min to about 100 g/min.

16. The method of any one of claims 15, wherein said at least one evaporant source has a diameter in the range of about 0.1 inch to about 10 inch.

17. The method of claim 16, wherein said at least one evaporant source has a diameter in the range of about 0.5 inch to about 1 inch.

18. The method of anyone of claims 1, 2, 3, 4, 5 and 6, wherein said evaporant source comprises at least one of Zirconium, Hafnium, mullite, alumina, silica, any oxide ceramic, ceria, zirconate, garnet, lanthanum aluminate, titania, any carbide, silicide or combination thereof.

19. The method of anyone of claims 1, 2, 3, 4, 5 and 6, wherein said evaporant source comprises at least one of any ceramic material or combination thereof.

20. The method of anyone of claims 1, 2, 3, 4, 5 and 6, wherein said evaporants have substantially the same chemical composition relative to one another.

21. The method of anyone of claims 1, 2, 3, 4, and 6, wherein said evaporants have different chemical composition relative to one another.

22. A method for forming a thermal barrier coating system, the method comprising:
presenting a substrate to a chamber, wherein said chamber has a down stream pressure, P_{c}, with an operating range from about 5 Pa to about 50 Pa;
depositing a bond coat on at least a portion of at least one said substrate;
presenting at least one evaporant source to said chamber;
presenting at least one carrier gas stream to said chamber, wherein said at least one carrier gas stream is generated from at least one nozzle;
impinging at least one said evaporant source with at least one energetic beam in said chamber to generate an evaporated vapor flux in a main direction respective for any of said evaporant sources impinged by said energetic beam, said at least one evaporant source is disposed in said nozzle;
said at least one carrier gas stream has a pressure ratio in the operating range from about 1 to about 100;
said substrate having a temperature in the range of about 15° C. and about 1250° C.;
said at least one evaporant source generates said evaporated vapor flux and an evaporation rate in the range of about 0.1 g/min to about 100 g/min;
deflecting at least one of said generated evaporated vapor flux by at least one of said carrier gas stream, wherein said carrier gas stream is essentially parallel to the main direction and substantially surrounds said evaporated flux, wherein said evaporated vapor flux at least partially coats at least one said substrate;
said chamber further includes a substrate bias system capable of applying a DC or alternating potential to at least one of said substrates;
impinging said at least one of said generated vapor flux and at least one of said carrier gas stream with a working gas generated by at least one hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

23. The method of claim 22, wherein said substrate having a temperature in the range of about 300° C. and about 1,250° C.

24. The method of claim 22, wherein said substrate having a temperature in the range of about 600° C. and about 1,250° C.

25. The method of claim 22, wherein said substrate having a temperature in the range of about 900° C. and about 1,250° C.

26. The method of any one of claims 22, 23, 24 and 25, wherein said at least one evaporant source has a diameter in the range of about 0.1 inch to about 10 inch.

27. The method of claim 26, wherein said at least one evaporant source has a diameter in the range of about 0.5 inch to about 1 inch.

28. The method of claim 22, said generated electrons from said hollow cathode source is regulated for direction through variations in the quantity of working gas passing through said hollow cathode source.

29. The method of claim 22, wherein the distance between said cathode source and said generated evaporated vapor flux is regulated for ionization of the entire generated evaporated vapor flux.

30. The method of any one of claims 22, 23, 24 and 25, wherein said at least one substrate is held stationary.

31. The method of any one of claims 22, 23, 24 and 25, wherein said at least one substrate is moved during at least a portion of the vapor flux coating.

32. The method of claim 31, wherein the movement comprises at least a partial rotation or multiple rotations.

33. The method of anyone of claims 22, 23, 24 and 25, wherein said evaporant source comprises at least one of Zirconium, Hafnium, mullite, alumina, silica, any oxide ceramic, ceria, zirconate, garnet, lanthanum aluminate, titania, any carbide, silicide and/or other ceramics, or combination thereof.

34. The method of anyone of claims 22, 23, 24 and 25, wherein said evaporant source comprises at least one of any ceramic material or combination thereof.

35. The method of anyone of claims 22, 23, 24 and 25, wherein said evaporants have substantially the same chemical composition relative to one another.

36. The method of anyone of claims 22, 23, 24 and 25, wherein said evaporants have different chemical composition relative to one another.

37. The method of claim 1 or 22, wherein said energetic beam comprises at least one of electron beam source, laser source, heat source, ion bombardment source, highly focused incoherent light source, microwave, radio frequency, EMF, or any energetic beam that break chemical bonds, or any combination thereof.

38. The method of claim 1 or 22, wherein said communication with said substrate is direct or indirect.

39. An apparatus for applying a thermal barrier coating system in communication with at least a portion of at least one substrate, said apparatus comprising:
a chamber, wherein said chamber has a down stream pressure, P_{c}, with an operating range from about 0.0001 Pa to about 150 Pa;
at least one evaporant source disposed in said chamber, said at least one evaporant source generates said evaporated vapor flux and an evaporation rate in the range of about 0.00001 g/min to about 100,000 g/min;
at least one carrier gas stream provided in said chamber, wherein said at least one carrier gas stream is generated from at least one nozzle, said at least one carrier gas stream has a pressure ratio in the operating range from about 1.01 to about 10,000,000; and
at least one energetic beam, said energetic beam:
impinging at least one said evaporant source with at least one energetic beam in said chamber to generate an evaporated vapor flux in a main direction respective for any of said evaporant sources impinged by said energetic beam,
deflecting at least one of said generated evaporated vapor flux by at least one of said carrier gas stream, wherein said carrier gas stream is essentially parallel to the main direction and substantially surrounds said evaporated flux, wherein said evaporated vapor flux at least partially coats at least one said substrate, and
said substrate having a temperature approximately equal to or greater than a melting point of said substrate.

40. The apparatus of claim 39, wherein said substrate having a temperature in the range of about 25° C. to about 1,250° C.

41. The apparatus of claim 39, wherein
said down stream pressure, P_{c}, has an operating range from about 0.1 Pa to about 20 Pa;
said at least one carrier gas stream has a pressure ratio in the operating range from about 1.01 to about 1,000; and
said substrate having a temperature approximately equal to or greater than a melting point of said substrate.

42. The apparatus of claim 41, wherein said substrate having a temperature in the range of about 900° C. to about 1,250° C.

43. The apparatus of claim 39, wherein
said down stream pressure, P_{c}) has an operating range from about 1 Pa to about 20 Pa;
said at least one carrier gas stream has a pressure ratio in the operating range from about 11 to about 1,000; and
said substrate having a temperature approximately equal to or greater than a melting point of said substrate.

44. The apparatus of claim 43, wherein said substrate having a temperature in the range of about 900° C. to about 1,250° C.

45. The apparatus of any one of claims 39, 40, 41, 42, 43 and 44, wherein said at least one substrate is held stationary during the deposition process.

46. The apparatus of any one of claims 39, 40, 41, 42, 43 and 44, wherein said at least one substrate is moved during at least a portion of the deposition process.

47. The apparatus of claim 46, wherein the movement comprises at least a partial rotation or multiple rotations.

48. The apparatus of anyone of claims 39, 40, 41, 42, 43 and 44, wherein said evaporant source comprises at least one of Zirconium, Hafnium, mullite, alumina, silica, any oxide ceramic, ceria, zirconate, garnet, lanthanum aluminate, titania, any carbide, silicide or combination thereof.

49. The apparatus of anyone of claims 39, 40, 41, 42, 43 and 44, wherein said evaporant source comprises at least one of any ceramic material or combination thereof.

50. The apparatus of anyone of claims 39, 40, 41, 42, 43 and 44, wherein said evaporants have substantially the same chemical composition relative to one another.

51. The apparatus of anyone of claims 39, 40, 41, 42, 43 and 44, wherein said evaporants have different chemical composition relative to one another.

52. An apparatus for applying a thermal barrier coating system in communication with at least a portion of at least one substrate, said apparatus comprising:
a chamber, wherein said chamber has a down stream pressure, P_{c}, with an operating range from about 5 Pa to about 50 Pa;
at least one evaporant source disposed in said chamber, said at least one evaporant source generates said evaporated vapor flux and an evaporation rate in the range of about 0.1 g/min to about 100 g/min;
at least one carrier gas stream provided in said chamber, wherein said at least one carrier gas stream is generated from at least one nozzle, said at least one carrier gas stream has a pressure ratio in the operating range from about 1 to about 100;
at least one energetic beam, said energetic beam:
impinging at least one said evaporant source with at least one energetic beam in said chamber to generate an evaporated vapor flux in a main direction respective for any of said evaporant sources impinged by said energetic beam,
deflecting at least one of said generated evaporated vapor flux by at least one of said carrier gas stream, wherein said carrier gas stream is essentially parallel to the main direction and substantially surrounds said evaporated flux, wherein said evaporated vapor flux at least partially coats at least one said substrate, and
said substrate having a temperature approximately equal to or greater than a melting point of said substrate; and
a substrate bias system capable of applying a DC or alternating potential to at least one of said substrates; and
at least one hollow cathode arc source generating a low voltage beam, said at least one hollow cathode arc source:
impinging said at least one of said generated vapor flux and at least one of said carrier gas stream with a working gas generated by at least one said hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

53. The apparatus of claim 52, wherein said substrate having a temperature in the range of about 300° C. and about 1,250° C.

54. The apparatus of claim 52, said generated electrons from said hollow cathode source is regulated for direction through variations in the quantity of working gas passing through said hollow cathode source.

55. The apparatus of claim 52, wherein the distance between said cathode source and said generated evaporated vapor flux is regulated for ionization of the entire generated evaporated vapor flux.

56. The apparatus of claim 39 or 52, wherein said energetic beam comprises at least one of electron beam source, laser source, heat source, ion bombardment source, highly focused incoherent light source, microwave, radio frequency, EMF, or any energetic beam that break chemical bonds, or any combination thereof.

57. The apparatus of claim 39 or 52, wherein said communication with said substrate is direct or indirect.
